(19) United States
(12) Patent Application Publication
(10) Pub. No.: US 2017/0032984 A1
(43) Pub. Date: Feb. 2, 2017

(54) LIQUID PROCESSING METHOD AND LIQUID PROCESSING APPARATUS

(71) Applicant: TOKYO ELECTRON LIMITED, Tokyo (JP)

(72) Inventors: Yudai ITO, Yamanashi (JP); Kazuya DOBASHI, Yamanashi (JP); Misako SAITO, Yamanashi (JP)

(21) Appl. No.: 15/219,430

(22) Filed: Jul. 26, 2016

(30) Foreign Application Priority Data
Jul. 29, 2015 (JP) 2015-149652

(51) Int. Cl. H01L 21/67; H01L 21/02; B03D 1/02; B01D 15/08; B01D 3/00; H01L 21/683; B08B 3/14

(52) U.S. Cl. CPC H01L 21/67051; H01L 21/6831; H01L 21/02057; B08B 3/14; B01D 15/08; B01D 3/00; B03D 1/02

(57) ABSTRACT

Disclosed is a method of performing a liquid processing on a workpiece by a liquid containing charged minute metal-containing impurities, using a liquid processing apparatus including: a holding unit configured to hold the workpiece; and a liquid supplying mechanism configured to supply a liquid to the workpiece held by the holding unit. The method includes: removing the metal-containing impurities contained in the liquid while supplying the liquid to the workpiece held by the holding unit; and/or controlling charging of the workpiece held by the holding unit to suppress the metal-containing impurities from being attached to the workpiece by an electrostatic force.

### CROSS-REFERENCE TO RELATED APPLICATIONS

This application is based on and claims priority from Japanese Patent Application No. 2015-149652 filed on Jul. 29, 2015 with the Japan Patent Office, the disclosure of which is incorporated herein in its entirety by reference.

### TECHNICAL FIELD

The present disclosure relates to a liquid processing method and a liquid processing apparatus for processing a workpiece with a liquid.

### BACKGROUND

In a manufacturing process of a semiconductor device, there is a liquid processing using a liquid such as, for example, a wet cleaning processing or a coating processing, on a semiconductor wafer which is a workpiece.

For example, in the wet cleaning processing, while a semiconductor wafer, which is a workpiece, is held in a rotary holding table and rotated, the semiconductor wafer is subjected to a chemical liquid cleaning processing with supply of a chemical liquid, such as, for example, an ammonia treatment, a hydrofluoric acid treatment, or a sulfuric acid treatment, and is rinsed with pure water. Thereafter, a dry processing is performed using isopropyl alcohol (IPA) as an organic solvent for drying, on the workpiece (see, e.g., Japanese Patent Laid-Open Publication No. 10-303173).

Since impurity particles are contained in the liquid used in the liquid processing, for example, IPA, and causes particulate contamination to the workpiece, the impurity particles are removed by, for example, a filter.

### SUMMARY

In a first aspect, the present disclosure provides a method of performing a liquid processing on a workpiece by a liquid containing charged minute metal-containing impurities, using a liquid processing apparatus including: a holding unit configured to hold the workpiece; and a liquid supplying mechanism configured to supply a liquid to the workpiece held by the holding unit. The method includes controlling charging of the workpiece held by the holding unit to suppress the metal-containing impurities from being attached to the workpiece by an electrostatic force.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic diagram illustrating a liquid processing apparatus for performing a liquid processing method of a first example in a first exemplary embodiment of the present disclosure.

FIGS. 2A and 2B are views for explaining a mechanism in which metal-containing impurities are suppressed from being adsorbed to a wafer in the liquid processing apparatus of FIG. 1.

FIG. 3 is a schematic diagram illustrating a liquid processing apparatus for performing a liquid processing method of a second example in the first exemplary embodiment of the present disclosure.

FIG. 4 is a view for explaining a mechanism in which metal-containing impurities are suppressed from being adsorbed to a wafer in the liquid processing apparatus of FIG. 3.

FIG. 5 is a schematic diagram illustrating a liquid processing apparatus for performing a liquid processing method of a third example in the first exemplary embodiment of the present disclosure.

FIGS. 6A and 6B are views for explaining a mechanism in which metal-containing impurities are suppressed from being adsorbed to a wafer in the liquid processing apparatus of FIG. 5.

FIG. 7 is a schematic diagram illustrating a liquid processing apparatus for performing a liquid processing method of a first example in a second exemplary embodiment of the present disclosure.

FIG. 8 is a view for explaining a mechanism in which metal-containing impurities are removed from the liquid in the liquid processing apparatus of FIG. 7.

FIG. 9 is a schematic diagram illustrating a liquid processing apparatus for performing a liquid processing method of a second example in the second exemplary embodiment of the present disclosure.

FIG. 10 is a view for explaining a mechanism in which metal-containing impurities are removed from the liquid in the liquid processing apparatus of FIG. 9.

FIG. 11 is a schematic diagram illustrating a liquid processing apparatus for performing a liquid processing method of a third example in the second exemplary embodiment of the present disclosure.

FIG. 12 is a schematic diagram illustrating a liquid processing apparatus for performing a liquid processing method of a fourth example in the second exemplary embodiment of the present disclosure.

FIG. 13 is a schematic diagram illustrating a liquid processing apparatus for performing a liquid processing method of a fifth example in the second exemplary embodiment of the present disclosure.

FIG. 14 is a graph schematically illustrating a charging state of material particles in coordinates of pH of the material particles and pH of a solvent.

FIG. 15 is a table illustrating a formula, polarity, and adsorption effect of Fe impurity particles in IPA for various organic materials.

FIG. 16 is a view for explaining a test in which a PFA tube is used as a liquid supply pipe, and IPA is sampled by frictionally charging the PFA tube.

FIG. 17 is a schematic diagram illustrating a liquid processing apparatus for performing a liquid processing method of a sixth example in the second exemplary embodiment of the present disclosure.

FIG. 18 is a schematic diagram illustrating a liquid processing apparatus for performing the liquid processing method of the second exemplary embodiment of the present disclosure, in which the ion removal filter of FIG. 11 is added to the liquid processing apparatus of FIG. 9.

FIG. 19 is a schematic diagram illustrating an exemplary liquid processing apparatus for performing a liquid processing method of a third exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

Even though impurity particles in IPA are removed by, for example, a filter, minute metal-containing impurities, which cannot be completely removed by the filter, are attached to a semiconductor wafer that is a workpiece. Thus, the characteristics of a semiconductor device may deteriorate.

Accordingly, an object of the present disclosure is to provide a liquid processing method and a liquid processing apparatus which can suppress minute metal-containing impurities from being attached to the workpiece when performing a liquid processing by supplying a liquid to the workpiece.

In order to achieve the object, the present inventors have studied on the reason that the minute metal-containing impurities are attached to a semiconductor wafer that is a workpiece, when performing an IPA processing on the semiconductor wafer. In the process, as a result of the review of a metal analysis technique in IPA, it has been found that minute metal-containing impurities, which are not detected by a conventional analysis technique, are present in the IPA, and a strong attachment of the minute metal-containing impurities to the semiconductor wafer that is a workpiece is promoted by an electrostatic force. This suggests that the minute metal-containing impurities present in the IPA are charged. As a result of further study on the basis of the finding, it is found that it is effective to perform a potential control of the workpiece such that the charged minute metal-containing impurities contained in a liquid for performing the liquid processing is not attached thereto, or to remove the charged minute metal-containing impurities using an electrostatic force or a metal adsorption material in a liquid supply line, thereby achieving the present disclosure.

In a first aspect, the present disclosure provides a method of performing a liquid processing on a workpiece by a liquid containing charged minute metal-containing impurities, using a liquid processing apparatus including: a holding unit configured to hold the workpiece; and a liquid supplying mechanism configured to supply a liquid to the workpiece held by the holding unit. The method includes controlling charging of the workpiece held by the holding unit to suppress the metal-containing impurities from being attached to the workpiece by an electrostatic force.

In a second aspect, the present disclosure provides a method of performing a liquid processing on a workpiece by a liquid containing charged minute metal-containing impurities, using a liquid processing apparatus including: a holding unit configured to hold the workpiece; and a liquid supplying mechanism configured to supply a liquid to the workpiece held by the holding unit. The method includes removing the metal-containing impurities contained in the liquid while supplying the liquid to the workpiece held by the holding unit.

In a third aspect, the present disclosure provides a method of performing a liquid processing on a workpiece by a liquid containing charged minute metal-containing impurities, using a liquid processing apparatus including: a holding unit configured to hold the workpiece; and a liquid supplying mechanism configured to supply a liquid to the workpiece held by the holding unit. The method includes removing the metal-containing impurities contained in the liquid while supplying the liquid to the workpiece held by the holding unit; and controlling charging of the workpiece held by the holding unit to suppress the metal-containing impurities remaining in the liquid from being attached to the workpiece by an electrostatic force.

In a fourth aspect, the present disclosure provides an apparatus for performing a liquid processing on a workpiece by a liquid containing charged minute metal-containing impurities. The apparatus includes a holding unit configured to hold the workpiece; and a liquid supplying mechanism configured to supply a liquid to the workpiece held by the holding unit. The apparatus further includes a charging controlling unit configured to control charging of the workpiece held by the holding unit, and the metal-containing impurities are suppressed from being attached to the workpiece by an electrostatic force, by the charging controlling unit.

In a fifth aspect, the present disclosure provides an apparatus for performing a liquid processing on a workpiece by a liquid containing charged minute metal-containing impurities. The apparatus includes a holding unit configured to hold the workpiece; and a liquid supplying mechanism configured to supply a liquid to the workpiece held by the holding unit. The the apparatus further includes a metal-containing impurity removing unit configured to remove the metal-containing impurities contained in the liquid while supplying the liquid to the workpiece held by the holding unit from the liquid supplying mechanism.

In a sixth aspect, the present disclosure provides an apparatus for performing a liquid processing on a workpiece by a liquid containing charged minute metal-containing impurities. The apparatus includes a holding unit configured to hold the workpiece; and a liquid supplying mechanism configured to supply a liquid to the workpiece held by the holding unit. The the apparatus further includes a metal-containing impurity removing unit configured to remove the metal-containing impurities contained in the liquid while supplying the liquid to the workpiece held by the holding unit from the liquid supplying mechanism; and a charging controlling unit configured to control charging of the workpiece held by the holding unit. The metal-containing impurities in the liquid are removed by the metal-containing impurity removing unit, and the metal-containing impurities remaining in the liquid are suppressed from being attached to the workpiece by an electrostatic force, by the charging controlling unit.

The charging of the workpiece may be controlled by grounding the holding unit. Further, the charging of the workpiece may be controlled by applying a DC voltage to the holding unit. Further, the charging of a front surface of the workpiece may be controlled by supplying pure water to a rear surface of the workpiece held by the holding unit.

The metal-containing impurities contained in the liquid may be removed by storing the liquid in a storage unit, immersing a pair of electrodes in the liquid in the storage unit, and applying a voltage between the electrodes to form an electric field, thereby trapping the metal-containing impurities contained in the liquid to the electrodes by the electrostatic force. In this case, the trapping of the metal-containing impurities to the electrodes may be facilitated by supplying microbubbles into the liquid stored in the storage unit from a lower side of the electrodes, and adsorbing the metal-containing impurities into the microbubbles while the microbubbles float in the liquid.

The metal-containing impurities may be removed by providing a filter capable of removing charged metal-containing impurities, in a liquid supply pipe configured to supply the liquid to the workpiece held by the holding unit. In this case, the filter may include a cation removal filter and an anion removal filter.

The metal-containing impurities may be removed from the liquid by distillatively purifying the liquid.

A material having a high adsorptivity with respect to the metal-containing impurities in the liquid may be used in at least a part of a liquid supply path configured to supply the liquid to the workpiece. Further, a metal-containing impurity removing unit including an adsorption member made of a material having a high adsorptivity with respect to the metal-containing impurities in the liquid may be provided in a liquid supply path configured to supply the liquid to the workpiece. The metal-containing impurities may be removed from the adsorption member after the metal-containing impurities are adsorbed to the adsorption member.

The material having a high adsorptivity with respect to the metal-containing impurities may have a surface potential in the liquid having a sign opposite to a charge or a surface potential of the metal-containing impurities in the liquid.

An index of the surface potential may be an isoelectric point obtained from a zeta potential or a zeta potential measurement of particles constituting the material having a high adsorptivity with respect to the metal-containing impurities. An index of the surface potential may be a dipole moment of composition of a compound constituting the material having a high adsorptivity with respect to the metal-containing impurities.

The material having a high adsorptivity with respect to the metal-containing impurities in the liquid may be charged.

In the present disclosure, it is newly found that the liquid used in the liquid processing contains charged minute metal-containing impurities, which have conventionally not been recognized as being contained therein. Based on this, the metal-containing impurities are suppressed from being attached to the workpiece by controlling charging of the workpiece, or removing the metal-containing impurities from the liquid, or performing both. Accordingly, metal contamination of the workpiece may be effectively suppressed.

Hereinafter, exemplary embodiments of the present disclosure will be described with reference to the drawings.

### First Exemplary Embodiment

First, a first exemplary embodiment will be described.

In the first exemplary embodiment, charged minute metal-containing impurities present in a liquid used for a liquid processing are suppressed from being attached by an electrostatic force to a wafer that is a workpiece, by controlling charging of the wafer that is a workpiece. Such minute metal-containing impurities typically have a particle-like shape and a size of 10 nm or less, but not limited thereto. The charged metal-containing impurities include an ionic form, but not limited to the ionic form.

### First Example

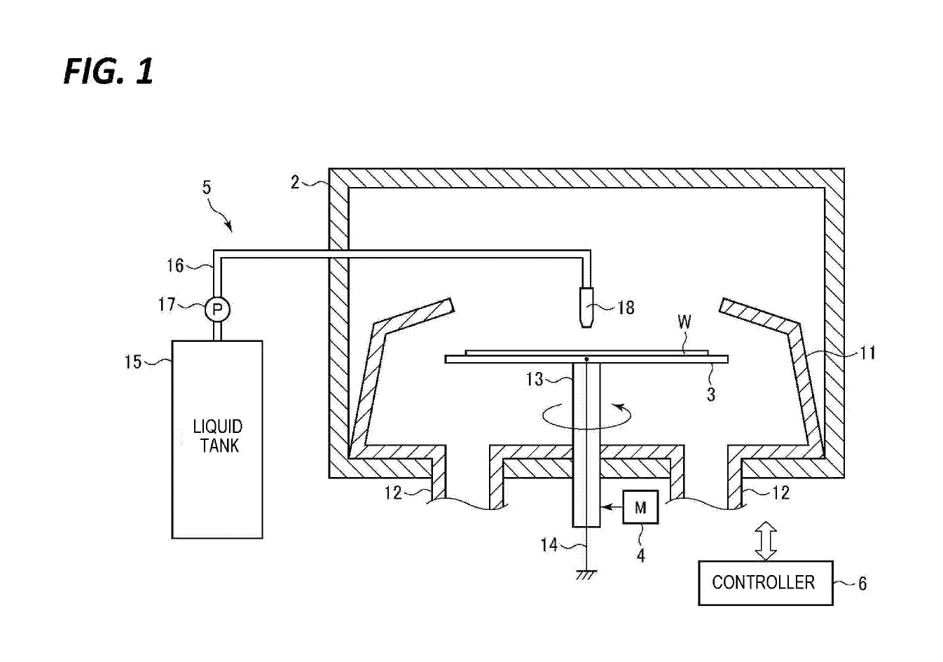

FIG. 1 is a schematic diagram illustrating a liquid processing apparatus for performing a liquid processing method of a first example in a first exemplary embodiment.

The liquid processing apparatus performs a single-wafer type liquid processing, for example, a cleaning processing, a drying processing, a coating processing, and the like on a semiconductor wafer (hereinafter, simply referred to as a “wafer”) W as a workpiece, and includes a chamber 2, a spin chuck 3 configured to rotatably hold the wafer W in the chamber 2, a motor 4 configured to rotate the spin chuck 3, a liquid supply mechanism 5 configured to supply a liquid to the wafer W held by the spin chuck 3, and a controller 6 configured to control respective parts of the liquid processing apparatus.

A cup 11 is provided in the chamber 2 to cover the wafer W held by the spin chuck 3. An exhaust/drain pipe 12 is provided in the bottom portion of the cup 11 to extend downwardly of the chamber 2. A carry-in/out port (not illustrated) is provided in the sidewall of the chamber 2 to perform a carry-in/out of the wafer W.

The spin chuck 3 holds the wafer W horizontally on its top surface. A cylindrical rotary shaft 13 is attached to the center of the spin chuck 3, and the rotary shaft 13 extends downwardly of the chamber 2. Then, when the rotary shaft 13 is rotated by the motor 4, the wafer W is rotated along with the spin chuck 3. The spin chuck 3 is grounded by a ground wire 14. The ground wire 14 extends to the outside of the chamber 2 through the inside of the rotary shaft 13.

The liquid supply mechanism 5 includes a liquid tank 15 provided outside the chamber 2 and configured to store a liquid for the liquid processing, a liquid supply pipe 16 configured to supply the liquid from the liquid tank 15 to the wafer W in the chamber 2, a liquid feeding pump 17 provided in the liquid supply pipe 16, and a nozzle 18 provided at the tip end of the liquid supply pipe 16. The liquid may be forcibly fed by N₂ gas or air instead of the pump 17. Further, the liquid supply pipe 16 is provided with an opening/closing valve, a flow rate controller, and a filter (all not illustrated). The nozzle 18 is configured to be movable in the radial direction of the wafer W and in the vertical direction by a driving mechanism (not illustrated). The driving mechanism moves the nozzle 18 between a liquid injection position just above the center of the wafer W and a retreat position retreated from the wafer W.

The liquid processing apparatus of this example performs a cleaning processing, a drying processing, a coating processing, and the like on the wafer W as a workpiece by supplying the liquid onto the wafer W as described above. In a case where the liquid processing apparatus 1 performs a processing with a plurality of liquids, for example, in a cleaning processing, a pure water rinse may be performed after chemical liquid cleaning, or a drying processing may be performed with, for example, IPA after the pure water rinse. Here, however, a case of supplying one kind of liquid will be described for convenience.

Any liquid commonly used for a liquid processing is available as the liquid used in the liquid processing. Examples thereof may include a chemical liquid used in the cleaning processing, for example, an aqueous solution of an ammonia-based chemical liquid (e.g., an ammonia-hydrogen peroxide mixture (APM)), a hydrofluoric acid-based chemical liquid (e.g., dilute hydrofluoric acid (DHF)), or a sulfuric acid-based chemical liquid (e.g., a sulfuric acid-hydrogen peroxide mixture (SPM)), or a solvent, pure water used in the rinse processing, a solvent used in the drying processing (e.g., IPA), and a thinner used in the coating processing. Those are applied similarly in the following examples and other exemplary embodiments.

The controller 6 includes a microprocessor (computer), and controls the rotation of the spin chuck 3 and the supply of the liquid. The controller 6 is configured to implement a predetermined processing recipe, and is provided with a storage unit that stores a control parameter or a processing recipe required for the implementation, an input unit, and a display.

Next, descriptions will be made on a liquid processing method performed by the liquid processing apparatus of the first example.

First, a wafer W to be subjected to a liquid processing is carried into the chamber 2 by a conveyance device (not illustrated), and mounted on the spin chuck 3. In this state, the nozzle 18 is moved from the retreat position to the liquid injection position just above the center of the wafer W. While the wafer W is rotated along with the spin chuck 3 by the motor 4, the liquid in the liquid tank 15 is supplied to the center of the wafer W through the liquid supply pipe 16 and the nozzle 18, and the liquid is dispersed to the entire surface of the wafer W, thereby performing the liquid processing.

At this time, in a case where minute metal-containing impurities, which are hardly removed by a typical filter, are contained in a state of being charged in the liquid, when the wafer W is charged with a potential of a sign opposite to the charge of the metal-containing impurities, the metal-containing impurities are attached strongly to the wafer W by an electrostatic force.

Further, the term “metal-containing impurities” include both a case of a single metal and a case of a compound such as, for example, a complex composed of metal atoms. The single metal is present in a positively charged (typically, cationic) state. However, the compound ion (e.g., a complex ion) may be present in a positively charged state or a negatively charged (typically anionic) state.

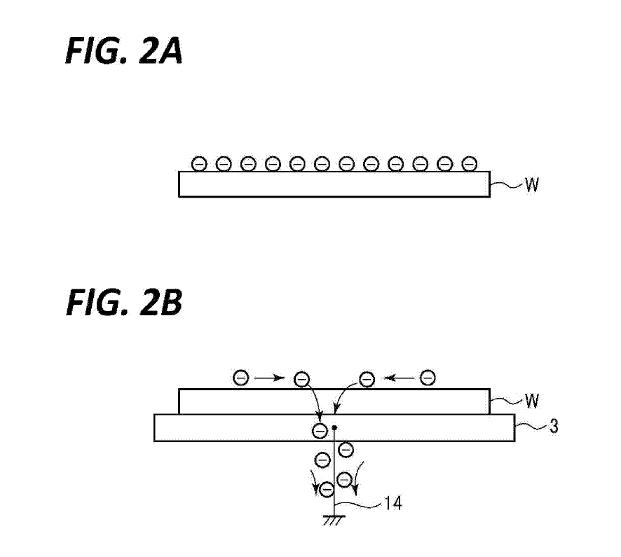

In this regard, in the present example, the ground wire 14 is connected to the spin chuck 3, and thus, the spin chuck 3 is grounded. Therefore, even in a case where the wafer W is charged as illustrated in FIG. 2A, when the wafer W is held on the spin chuck 3, the charges of a front surface of the wafer W flow to the ground through the ground wire 14 as illustrated in FIG. 2B. Accordingly, the wafer W on the spin chuck 3 comes into a state where the charging is substantially canceled. Thus, the metal-containing impurities may be suppressed from being attached to the wafer W by the electrostatic force during the liquid processing.

Especially, in a case of using a liquid having a small total number of ions such as, for example, a solvent having a low self-dissociation constant [pkap] (a self-dissociation constant of 14 or less) (e.g., IPA) or an aprotic polar solvent (e.g., acetone or a thinner), metal-containing impurities present in an ionic form in the liquid tend to be attached to the charged wafer W. Thus, the metal-containing impurities are attached to the wafer W in a large amount. Similarly, in an aqueous solution having few protons or other cations in the liquid, metal-containing impurities present as cations in the liquid tend to be attached to the wafer W. In an aqueous solution having few anions (e.g., F⁻, Cl⁻, and OH⁻) in the liquid, metal-containing impurities present as anions in the liquid tend to be attached to the wafer W. Therefore, the method of the present example is particularly effective in the case of using such a liquid. Incidentally, this point is applied similarly in other examples and other exemplary embodiments to be described below.

### Second Example

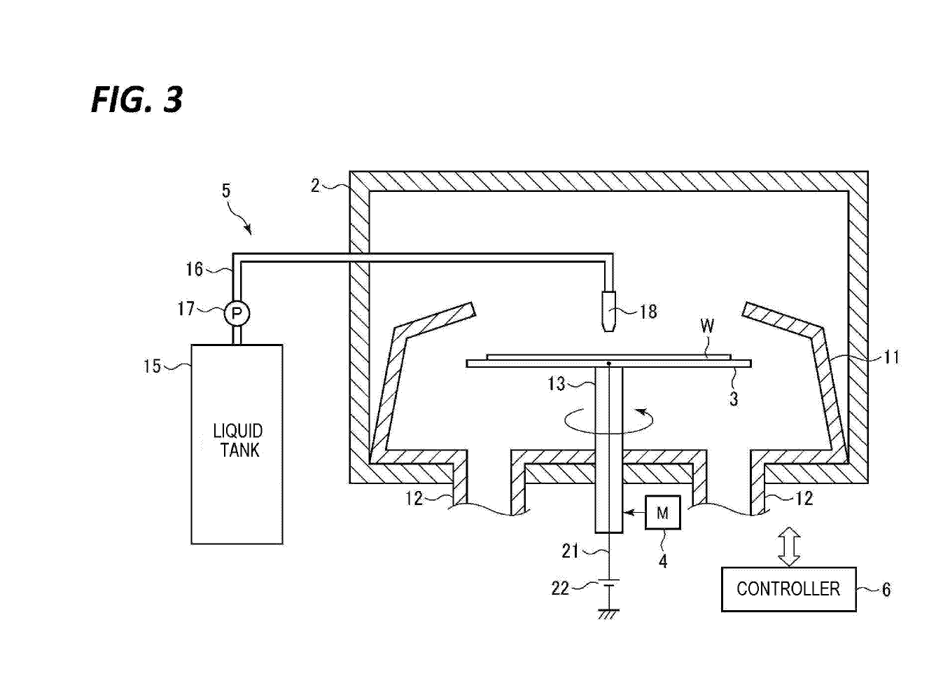

FIG. 3 is a schematic diagram illustrating a liquid processing apparatus for performing a liquid processing method of a second example in the first exemplary embodiment.

In the liquid processing apparatus of the first example of FIG. 1, the ground wire 14 is provided as a unit for canceling the charging of the wafer. However, in the liquid processing apparatus of the present example, the spin chuck 3 is connected with a DC power source 22 via a feed line 21 instead of the ground wire 14, so that a voltage is applied to the spin chuck 3. Others are configured similarly to the liquid processing apparatus of FIG. 1. Therefore, descriptions of the same portions as in FIG. 1 will be omitted.

The feed line 21 extends from the spin chuck 3 to the outside of the chamber 2 through the inside of the rotary shaft 13, and the DC power source 22 is connected to a portion of the feed line 21 outside the chamber 2. Then, the spin chuck 3 is applied with a DC voltage of the same sign as that of the metal-containing impurities, which are desired to be suppressed from being attached, present in the liquid, from the DC power source 22. For example, when the metal-containing impurities, which are desired to be suppressed from being attached, are positively charged (cations), the spin chuck 3 is applied with a positive voltage.

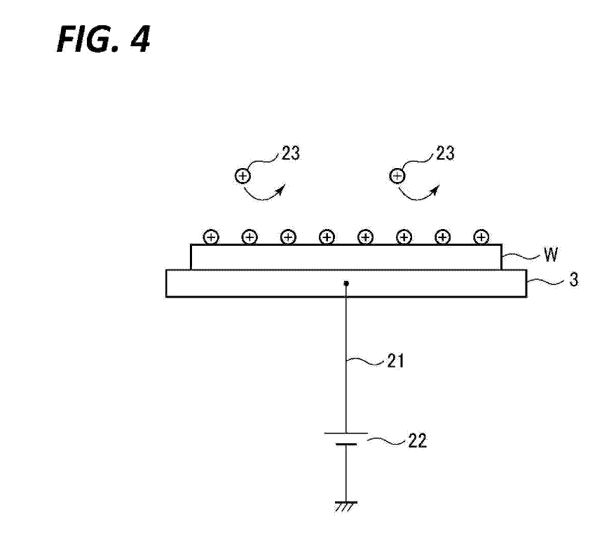

As such, when the spin chuck 3 is applied with a positive voltage, the wafer W is positively charged as illustrated in FIG. 4, so that metal-containing impurities 23 present as cations in the liquid are repulsed from the wafer W. Thus, the attachment of the metal-containing impurities to the wafer W by the electrostatic force may be suppressed more effectively than the first example.

### Third Example

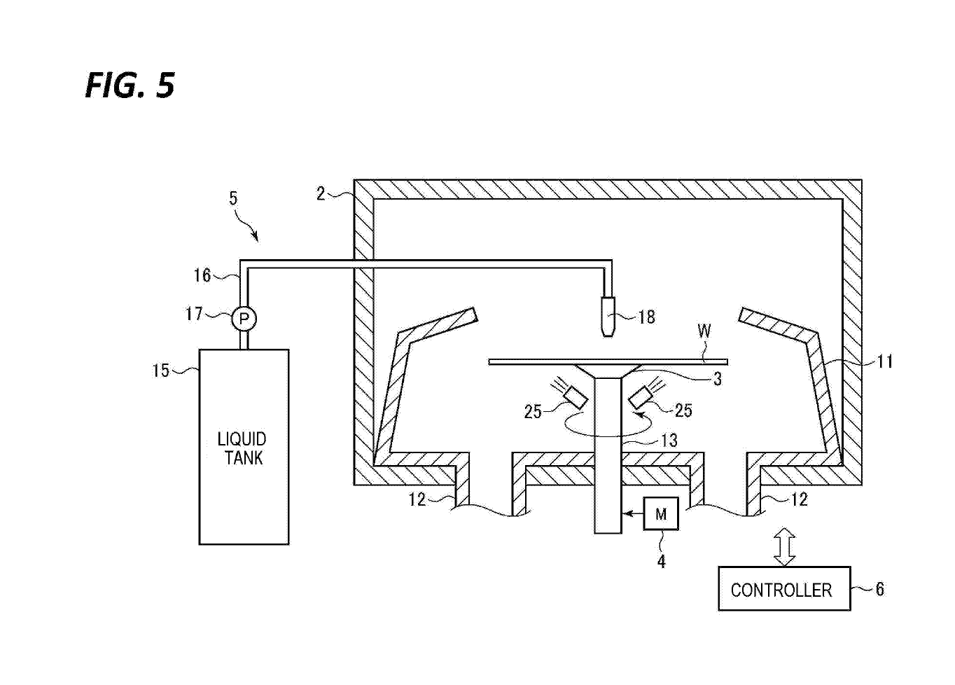

FIG. 5 is a schematic diagram illustrating a liquid processing apparatus for performing a liquid processing method of a third example in the first exemplary embodiment.

The liquid processing apparatus of the present example uses a back rinse nozzle 25 as a unit for canceling the charging of the wafer, unlike the first example and the second example. Other configurations are basically similar to the liquid processing apparatus of FIG. 1. Thus, descriptions for the same parts as in FIG. 1 will be omitted.

In the present example, the spin chuck 3 is provided in the central portion of the wafer W, and the wafer W is held on the spin chuck 3 in a state where the rear surface of the wafer W is exposed. In addition, a plurality of back rinse nozzles 25 are provided to supply pure water as a rinse liquid to the rear surface of the wafer W.

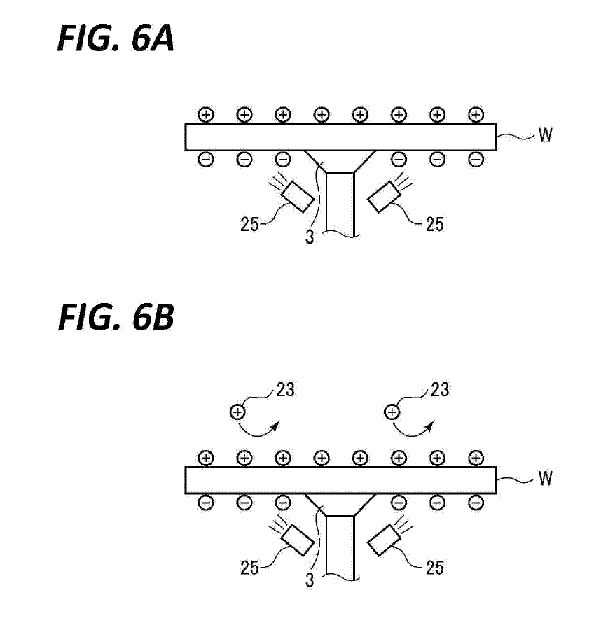

When pure water is supplied as a rinse liquid from the back rinse nozzles 25 to the rear surface of the wafer W, the rear surface of the wafer W is negatively charged and the front surface of the wafer W is positively charged by induction charging, as illustrated in FIG. 6A. Thus, as illustrated in FIG. 6B, the metal-containing impurities 23 present in a positively charged state, for example, as cations in the liquid, are repulsed from the front surface of the wafer W, so that the metal-containing impurities are suppressed from being attached to the front surface of the wafer W by the electrostatic force.

Descriptions will be made on an exemplary case where a drying processing with IPA is subsequently performed after the pure water rinse of the front surface of the wafer W. Although the front surface of the wafer W is negatively charged by the pure water rinse, the front surface of the wafer W is positively charged by performing a back rinse before changing to the IPA drying processing. Thus, during the IPA drying processing, the minute metal-containing impurities present in a positively charged state, for example, as cations in the IPA, may be suppressed from being attached to the front surface of the wafer W.

### Second Exemplary Embodiment

Next, a second exemplary embodiment will be described.

In the second exemplary embodiment, charged minute metal-containing impurities present in the liquid are removed from a supply system of the liquid used in the liquid processing, so that the metal-containing impurities are suppressed from being attached to a wafer that is a workpiece. Similarly to the first exemplary embodiment, the minute metal-containing impurities typically have a particle-like shape and a size of 10 nm or less, but not limited thereto. The charged metal-containing impurities include an ionic form, but not limited to the ionic form.

### First Example

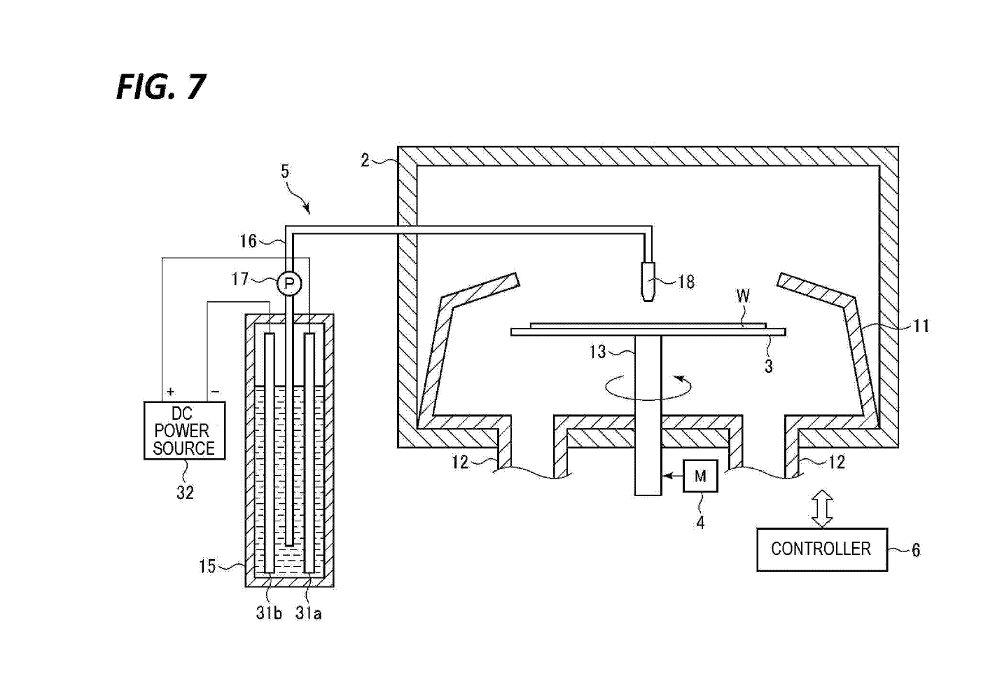

FIG. 7 is a schematic diagram illustrating a liquid processing apparatus for performing a liquid processing method of a first example in a second exemplary embodiment.

Although the wafer charging controlling unit of the first exemplary embodiment is not provided, the liquid processing apparatus of the present example includes a pair of electrodes 31a, 31b immersed in the liquid in the liquid tank 15, and a DC power source 32 configured to apply a voltage to the electrodes, as a unit for removing metal-containing impurities in the liquid. Others are configured basically similarly to the liquid processing apparatus of the first example in the first exemplary embodiment illustrated in FIG. 1. Therefore, descriptions of the same portions as in FIG. 1 will be omitted.

In the present example, a pair of electrodes 31a, 31b are immersed in the liquid stored in the liquid tank 15. The electrodes 31a, 31b are made of, for example, silicon (Si). The electrode 31a is an anode connected to the positive side of the DC power source 32, and the electrode 31b is a cathode connected to the negative side of the DC power source 32.

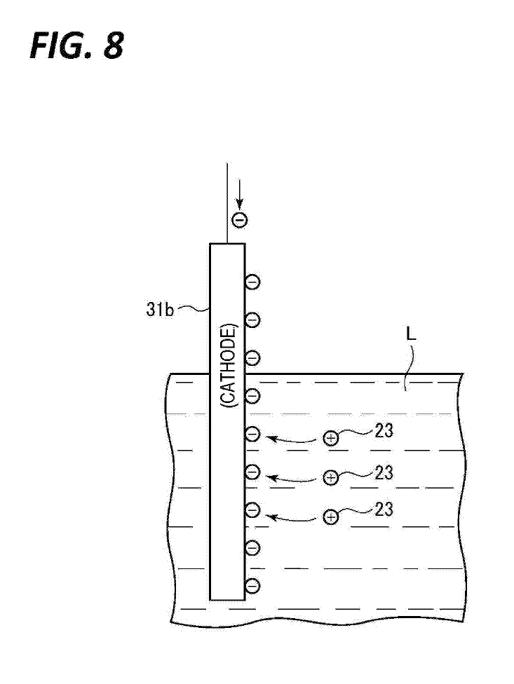

When a voltage is applied from the DC power source 32 to the electrodes 31a, 31b to form an electric field in the liquid tank 15, charged substances (ions) in the liquid may be trapped by the electrostatic force. For example, as illustrated in FIG. 8, when minute metal-containing impurities are present in a positively charged state, for example, as cations in a liquid L, the metal-containing impurities 23 are trapped (adsorbed) to the negatively charged electrode 31b, so that the metal-containing impurities are removed from the liquid. Accordingly, the minute metal-containing impurities in the liquid may be suppressed from being attached to the wafer that is a workpiece during the liquid processing.

Further, the metal-containing impurities may be trapped by providing an electrode in a pipe to form an electric field in the liquid supply pipe.

### Second Example

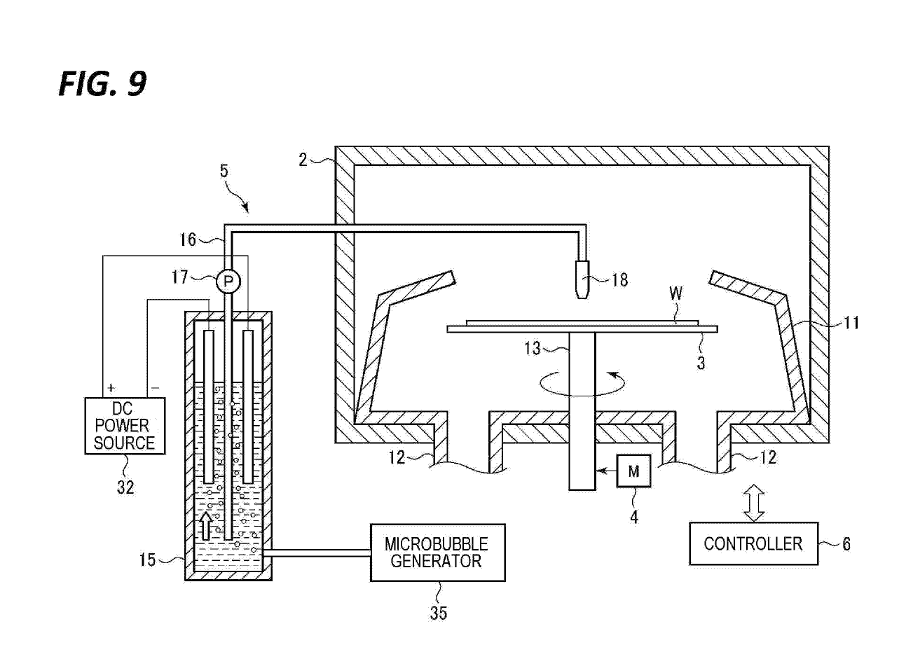

FIG. 9 is a schematic diagram illustrating a liquid processing apparatus for performing a liquid processing method of a second example in the second exemplary embodiment.

The liquid processing apparatus of the present example is configured by adding a microbubble generator 35 to the liquid processing apparatus of the first example of FIG. 7. Others are configured exactly in the same manner as the liquid processing apparatus of FIG. 7.

The microbubble generator 35 is connected to the liquid tank 15 and configured to supply microbubbles into the liquid in the liquid tank 15. The microbubble generator 35 is connected to the bottom portion of the liquid tank 15, and the lower ends of the electrodes 31a, 31b are positioned above a microbubble introducing portion.

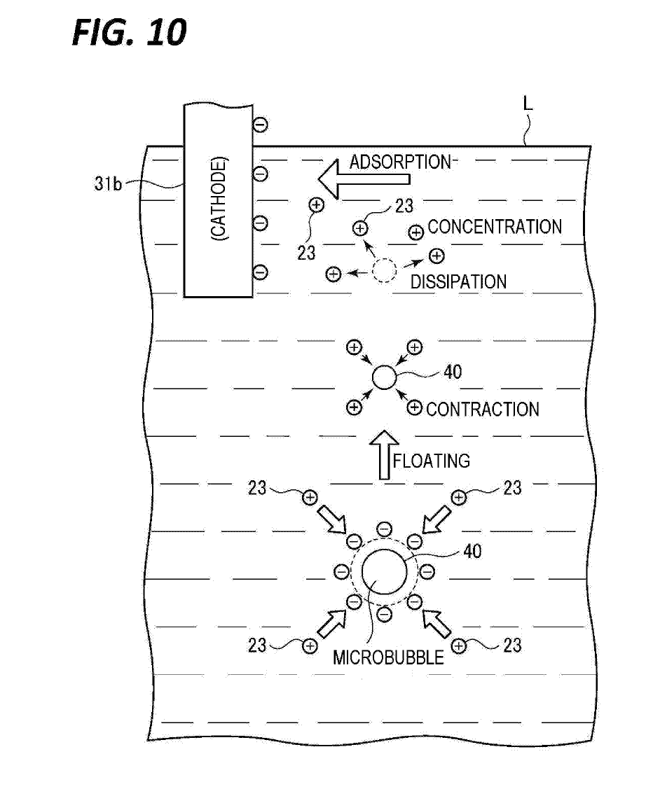

As such, microbubbles are supplied from the microbubble generator 35 into the liquid L in the liquid tank 15. As illustrated in FIG. 10, since a zeta potential is generated on the surface of a microbubble 40 in the liquid, the metal-containing impurities 23 in a positively charged state (cations) in the liquid are adsorbed onto the surface of the microbubble 40. Then, the microbubble 40 contracts in a floating process while adsorbing the metal-containing impurities 23, and eventually dissipates, so that the metal-containing impurities 23 are concentrated. Since the metal-containing impurities are thus concentrated, the movement of the metal-containing impurities 23 to the electrode 31b (cathode) is facilitated. Therefore, the adsorption efficiency of the metal-containing impurities 23 to the electrode 31b is enhanced as compared with the first example, and the removal efficiency of the metal-containing impurities becomes higher than that in the first example. Accordingly, the minute metal-containing impurities in the liquid may be more efficiently suppressed from being attached to the wafer that is a workpiece during the liquid processing.

### Third Example

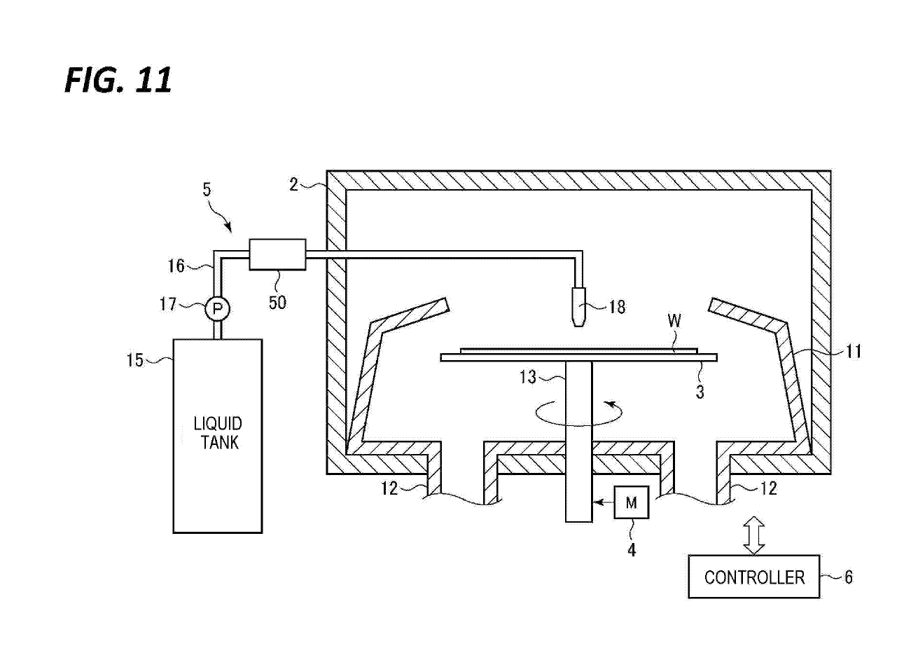

FIG. 11 is a schematic diagram illustrating a liquid processing apparatus for performing a liquid processing method of a third example in the second exemplary embodiment.

In the present example, a filter 50 capable of removing charged metal-containing impurities is provided in the liquid supply pipe 16 extending from the liquid tank 15. When the filter 50 is used as a cation removal filter, positively charged metal-containing impurities (cations) may be removed. In addition, when the filter 50 is used as an anion removal filter, negatively charged metal-containing impurities (anions) may be removed. Specifically, as the filter 50, the cation removal filter and the anion removal filter may be used in combination. Therefore, since the positively charged metal-containing impurities (cations) and the negatively charged metal-containing impurities (anions) are removed from the liquid, the amount of the metal-containing impurities in the liquid may be further reduced. Thus, the metal-containing impurities may be more efficiently suppressed from being attached to the wafer W during the liquid processing.

### Fourth Example

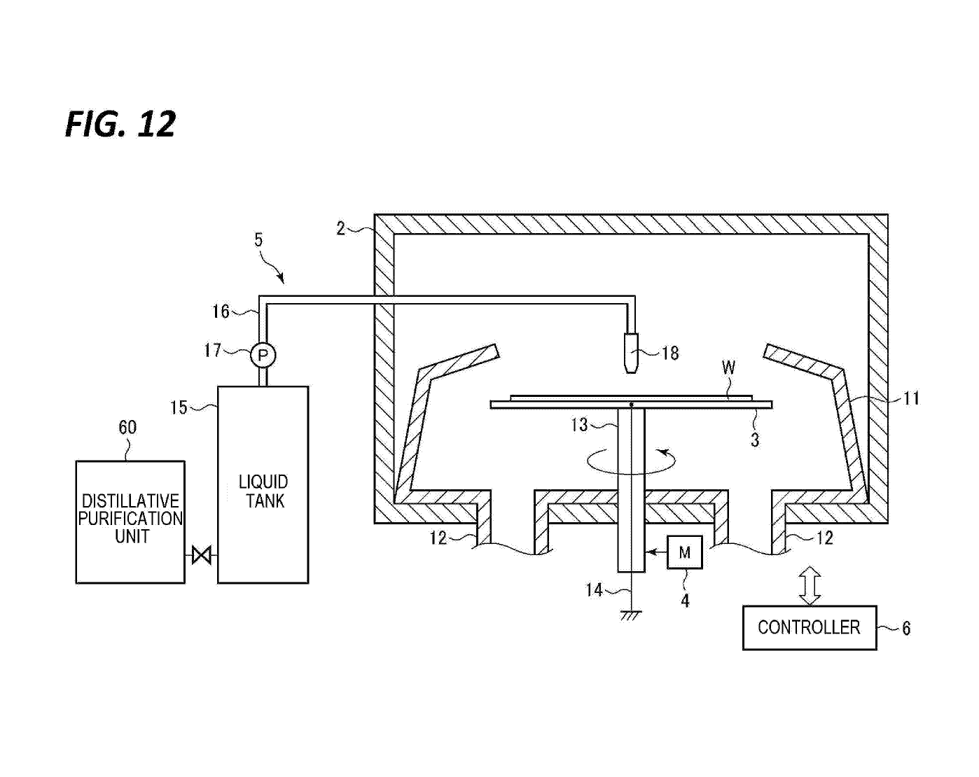

FIG. 12 is a schematic diagram illustrating a liquid processing apparatus for performing a liquid processing method of a fourth example in the second exemplary embodiment.

In the present example, a distillative purification unit 60 is provided to distillatively purify a liquid supplied to the liquid tank 15. When a solvent or pure water is used as the liquid, minute metal-containing impurities in the liquid may be removed by distillatively purifying the liquid. Thus, the number of metal-containing impurities in the liquid supplied to the wafer W during the liquid processing may be reduced. Therefore, the metal-containing impurities may be suppressed from being attached to the wafer W.

### Fifth Example

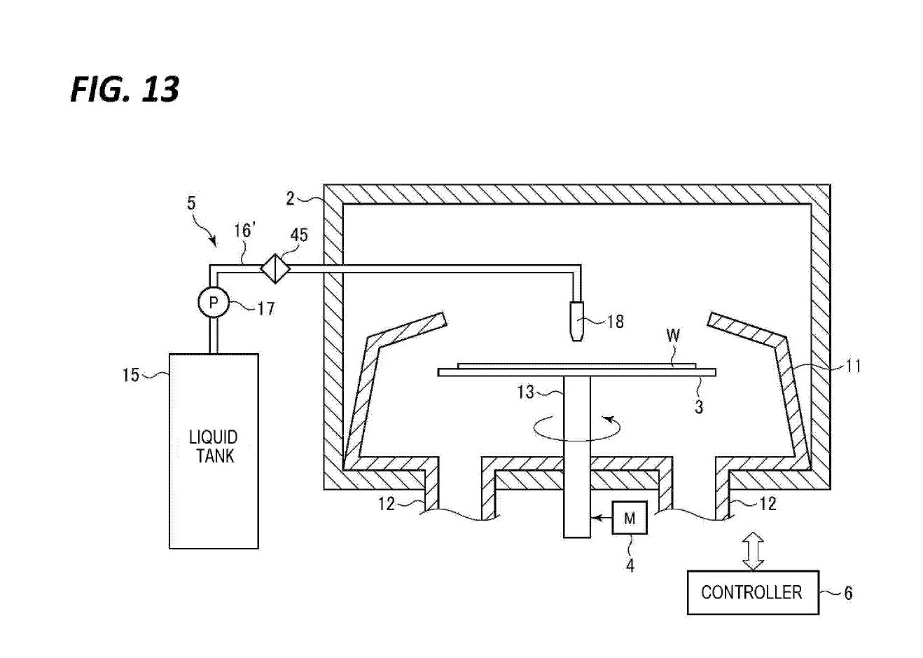

FIG. 13 is a schematic diagram illustrating a liquid processing apparatus for performing a liquid processing method of a fifth example in the second exemplary embodiment.

In the present example, instead of the liquid supply pipe 16 in the previous examples, a liquid supply pipe 16′ made of a material having a high adsorptivity with respect to charged minute metal-containing impurities in the liquid is provided, and an impurity removal filter 45 made of a material having a high adsorptivity with respect to the same metal-containing impurities is provided in the liquid supply pipe 16′.

As such, when a material having a high adsorptivity with respect to metal-containing impurities in the liquid is used in the liquid supply path, minute metal-containing impurities in the liquid is trapped and removed in the liquid supply path.

Hereinafter, the process that led to the configuration will be described.

In a case where the liquid is IPA, it is found that impurities mainly containing Fe (Fe impurities) are present in the IPA, and when the IPA is placed into a perfluoroalkoxyakane (PFA) container, the Fe impurities in the IPA are adsorbed onto the inner wall of the container with high efficiency. Further, it is found that, when IPA is coated on a silicon wafer, the Fe impurities are adsorbed to the wafer with high efficiency. From this finding, even in a case where Si is used as a material for the container, it is expected that the Fe impurities in the IPA may be adsorbed onto the inner wall of the container with high efficiency as well.

On the other hand, it is found that, when IPA is placed into a polypropylene (PP) container, the Fe impurities in the IPA are hardly adsorbed onto the inner wall of the container. Further, a data has been obtained, suggesting that the Fe impurities in the IPA are also hardly adsorbed onto polytetrafluoroethylene (PTFE) which is a material for a particle removal filter widely used as a material of the IPA supply line.

Such adhesion of the material with the metal-containing impurities in a liquid depends on the surface potential (negative or positive) of the material in a target liquid, or the polarity of the material itself (whether positive or negative charges are unevenly distributed). Specifically, when the liquid is IPA, the material to which the Fe impurities in the liquid are easily attached is a material of which the surface potential becomes negative for the IPA, or a material having a portion where electrically negative charges are unevenly distributed due to the polarity of the material itself.

An index of the surface potential of material particles may include an isoelectric point (a pH at which the charge average of the material particles after ionization becomes zero (0)) obtained from a zeta potential or a zeta potential measurement of the material particles. Even in the charging of the particles in an organic solvent such as IPA, the zeta potential measured in an aqueous solvent becomes an index of the surface potential.

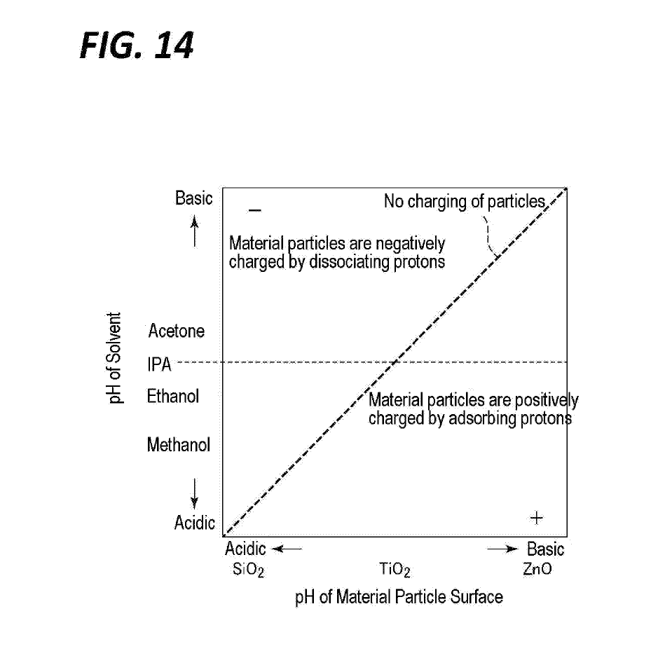

FIG. 14 is a graph schematically illustrating a charging state of material particles in coordinates of pH of the material particles and pH of a solvent. From the figure, it is understood that the SiO₂ surface has a negative potential in the IPA solvent. Since the Fe impurities in the IPA are adsorbed onto the SiO₂ film surface with high efficiency, it is considered that most of the Fe impurities have positive charges, and are electrically adsorbed onto the SiO₂ surface. Therefore, the material to which the Fe impurities in the IPA are easily adsorbed is a material of which the surface potential becomes negative for the IPA.

The index of the horizontal axis in FIG. 14 is summarized in terms of the isoelectric point, and noted in Table 1 below. From FIG. 14 and Table 1, it is found that the Fe-based impurity particles in the IPA are easily adsorbed onto a material having a low isoelectric point such as SiO₂, and hardly adsorbed onto a material having a high isoelectric point such as ZnO.

TABLE 1

| Material Name | SiO₂ | TiO₂ | ZnO |
|---|---|---|---|
| Isoelectric Point (pH°) | 1.8~2.8 | 5.5~6.7 | 7.5 |

Further, when a film having a low isoelectric point such as SiO₂ is formed on the surface of the wafer, the Fe impurities in the IPA are easily adsorbed. Therefore, it is effective to suppress the adhesion of the Fe impurities onto the wafer by grounding the wafer or applying a voltage as described in the first exemplary embodiment.

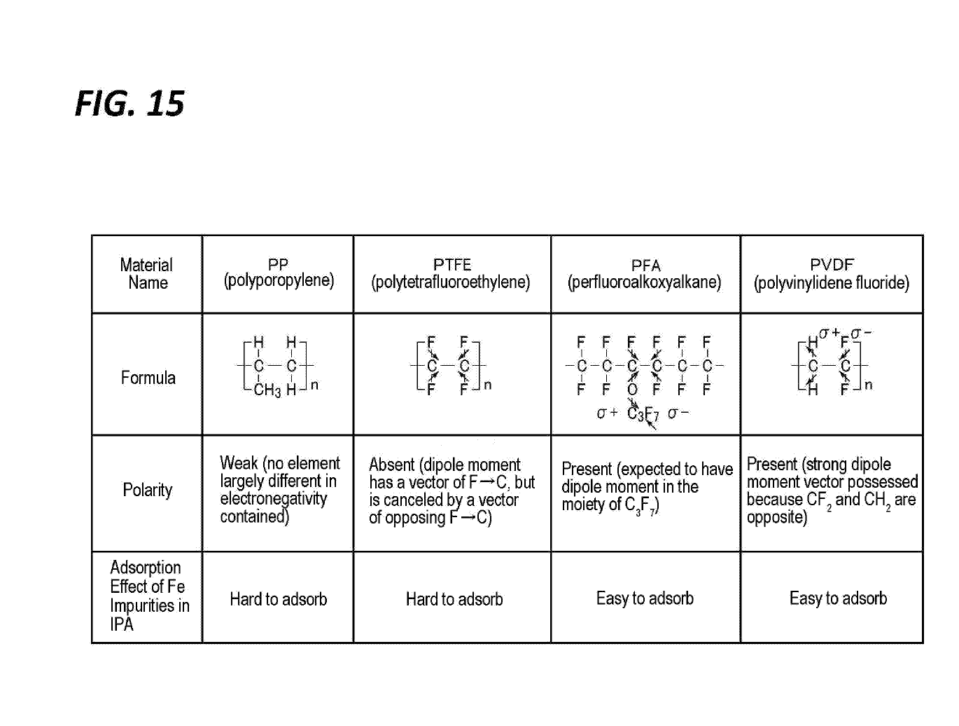

An index of the polarity of the material particles may include a dipole moment of composition of a compound. The dipole moment is an index particularly for organic materials. That is, a polar material containing elements which are different in electronegativity and having a high dipole moment due to the induced polarity has a portion where electrically negative charges are unevenly distributed, and thus, easily adsorb the Fe impurities in the IPA. A formula, polarity, and adsorption effect of Fe impurity particles in IPA for various organic materials are integrally illustrated in FIG. 15.

As illustrated in FIG. 15, PP (polypropylene) has a weak polarity because it contains no element largely different in electronegativity in its structural formula. Thus, PP has a low adsorptivity with respect to the Fe impurities in the IPA (hard to adsorb). Further, PTFE (polytetrafluoroethylene) has a vector of F→C, but the vector is canceled by a vector of opposing F→C, and thus, no polarity is induced. Thus, PTFE also has a low adsorptivity with respect to the Fe impurities in the IPA (hard to adsorb). On the contrary, it is expected that PFA (perfluoroalkoxyalkane) has a dipole moment induced by C₃F₇ in the structural formula. Thus, PFA has a high adsorptivity with respect to the Fe impurities in the IPA (easy to adsorb). Further, PVDF (polyvinylidene fluoride) has a strong dipole moment vector because the vectors of CF₂ and CH₂ in the structural formula are opposite. Thus, PVDF has a high adsorptivity with respect to the Fe impurities in the IPA (easy to adsorb). For PP, PTFE, and PFA among the materials, the adsorptivity with respect to the Fe impurities in the IPA is substantially demonstrated.

As described above, in the present exemplary embodiment, a material which easily adsorbs charged minute metal-containing impurities in the liquid is used in the liquid supply path. Additionally, even higher adsorptivity may be expected by charging the material in the liquid supply path.

For example, a material that constitutes a liquid supply pipe 16′ and easily adsorbs minute metal-containing impurities in a liquid is a material having a surface potential of a polarity opposite to that of the minute metal-containing impurities in the liquid. Therefore, when the material is charged by friction with, for example, a polyester wipe, so that the surface potential of the liquid supply pipe 16′ is further increased, the material may adsorb the metal-containing impurities with higher efficiency.

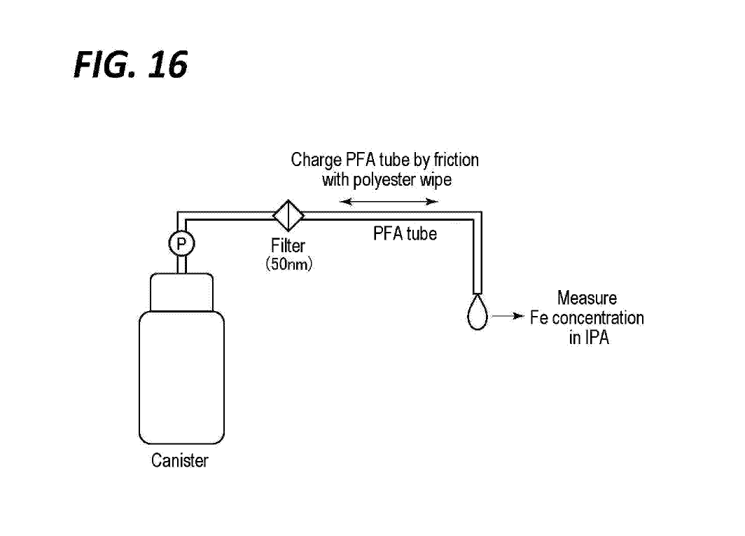

In practice, as illustrated in FIG. 16, a PFA tube was used as the liquid supply pipe, and a filter capable of removing 50-nm particles was used as the particle removal filter. Then, a Fe concentration in IPA supplied from the container (canister) via the supply pipe in a state where the PFA tube is frictionally charged, was compared with a Fe concentration in IPA in a case where the PFA tube is not frictionally charged.

As a result, the Fe concentration in the sampled IPA was 61 ppt in the case where the PFA tube was not frictionally charged, while the concentration was 25 ppt in the case where the PFA tube was frictionally charged. Thus, it was confirmed that the amount of the Fe-based impurity particles in the IPA was reduced by about 60%.

Further, in the present example, the material having a high adsorptivity with respect to the metal-containing impurities in the liquid was applied to both of the liquid supply pipe and the particle removal filter, but may be applied to either of them. Further, the liquid tank may be made of a material having a high adsorptivity with respect to the metal-containing impurities.

Further, in a case of charging, at least one of the liquid supply path members made of a material having a high adsorptivity with respect to the metal-containing impurities in the liquid may be charged.

### Sixth Example

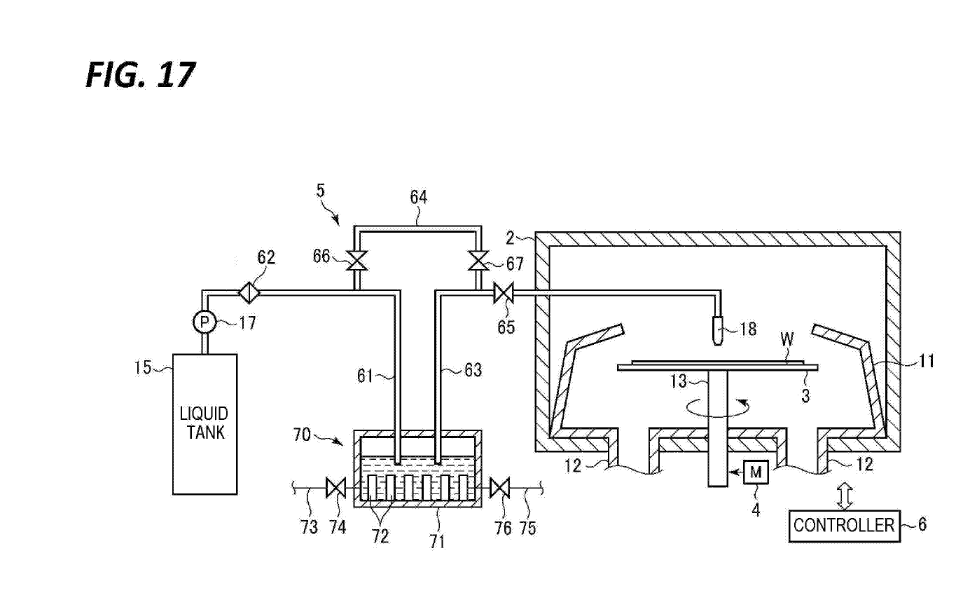

FIG. 17 is a schematic diagram illustrating a liquid processing apparatus for performing a liquid processing method of a sixth example in the second exemplary embodiment.

In the present example, the liquid supplying mechanism 5 is provided with a cleaning unit (metal-containing impurity removal unit) 70 using the material having a high adsorptivity with respect to metal-containing impurities in the liquid of the fifth example.

Specifically, a first liquid supply pipe 61 for supplying a liquid such as, for example, IPA extends from the liquid tank 15, and a pump 17 and a impurity removal filter 62 are interposed in the first liquid supply pipe 61. The first liquid supply pipe 61 is inserted into the cleaning unit 70 from the top, and the liquid is supplied to the cleaning unit 70 through the first liquid supply pipe 61 and stored therein. In addition, a second liquid supply pipe 63 is inserted into the cleaning unit 70 from the top thereof. The second liquid supply pipe 63 extends into the chamber 2 and is provided with a nozzle 18 at the tip end thereof.

The first liquid supply pipe 61 and the second liquid supply pipe 63 are connected by a circulation line 64. Further, an opening/closing valve 65 is provided at the downstream side of a connecting portion of the second liquid supply pipe 63 with respect to the circulation line 64. The circulation line 64 is provided with an opening/closing valve 66 near the connecting portion with the first liquid supply pipe 61, and an opening/closing valve 67 near the connecting portion with the second supply pipe 63. Accordingly, the operations of the opening/closing valves 65, 66, 67 enable to switch between a mode of supplying the liquid to the wafer and a mode of circulating the liquid in the circulation line 64.

The cleaning unit 70 is configured as a batch-type cleaning unit, and provided with an adsorption bath 71 and an adsorption member 72 laid on the bottom of the adsorption bath 71. The adsorption member 72 is made of the material having a high adsorptivity with respect to metal-containing impurities in the liquid of the fifth example.

Further, the adsorption bath 71 is connected with a regeneration liquid supply line 73 and a regeneration liquid discharge line 75, which are interposed with an opening/closing valve 74 and an opening/closing valve 76, respectively. A regeneration liquid is used to remove the metal-containing impurities trapped in the adsorption member 72. Typically, an acid solution is used.

In the liquid processing apparatus of the present example, for example, IPA is supplied as the liquid from the liquid tank 15 to the adsorption bath 71 of the cleaning unit 70 through the first liquid supply pipe 61. At this time, the opening valves 65, 66, 67 are closed. After the completion of the supply of the liquid and a lapse of a certain period of time, the valve 65 is opened to supply the liquid to the wafer through the second liquid supply pipe 63 and the nozzle 18. Accordingly, in the adsorption bath 71, the metal-containing impurities in the liquid are adsorbed onto the adsorption member 72.

Accordingly, the metal-containing impurities in the liquid may be removed with high efficiency by being adsorbed onto the adsorption member 72. Further, the adsorption material may have a structure that increases the adsorption efficiency, for example, by forming the material in a spherical shape or in a porous form to enlarge the adsorption surface area.

When the liquid processing is not performed, the opening/closing valve 65 is closed, and the opening/closing valves 66, 67 are opened, so that the liquid is circulated by the circulation line 64.

When the adsorption member 72 adsorbs a predetermined amount of the metal-containing impurities, it becomes difficult to adsorb more than the amount. Thus, it is desired to remove the metal-containing impurities trapped in the adsorption member 72 and regenerate the adsorption member 72. In the regeneration of the adsorption member 72, a regeneration liquid, for example, an acid solution is supplied to the adsorption bath 71 through the regeneration liquid supply line 73 in a state where no liquid is in the adsorption bath 71, so that the metal-containing impurities adsorbed onto the adsorption member 72 are removed. After the completion of the regeneration processing, the regeneration liquid is discharged from the regeneration liquid discharge line 75.

Further, the cleaning unit may be a continuous type that allows the liquid to flow into the adsorption bath from the lower portion thereof and flow out of the adsorption bath from the upper portion thereof. In addition, the content of the fifth example may be applied to the adsorption member of the present example.

### Other Examples

In the second exemplary embodiment, the first to sixth examples may be appropriately combined. For example, the ion removal filter 50 of the third example or the distillation generating unit 60 of the fourth example may be provided in the liquid processing apparatus of the first example illustrated in FIG. 7 or the liquid processing apparatus of the second example illustrated in FIG. 9, or both may be provided therein. Thus, the removal ratio of the metal-containing impurities in the liquid may be further enhanced. Therefore, the metal-containing impurities may be more efficiently suppressed from being attached to the wafer W during a liquid processing.

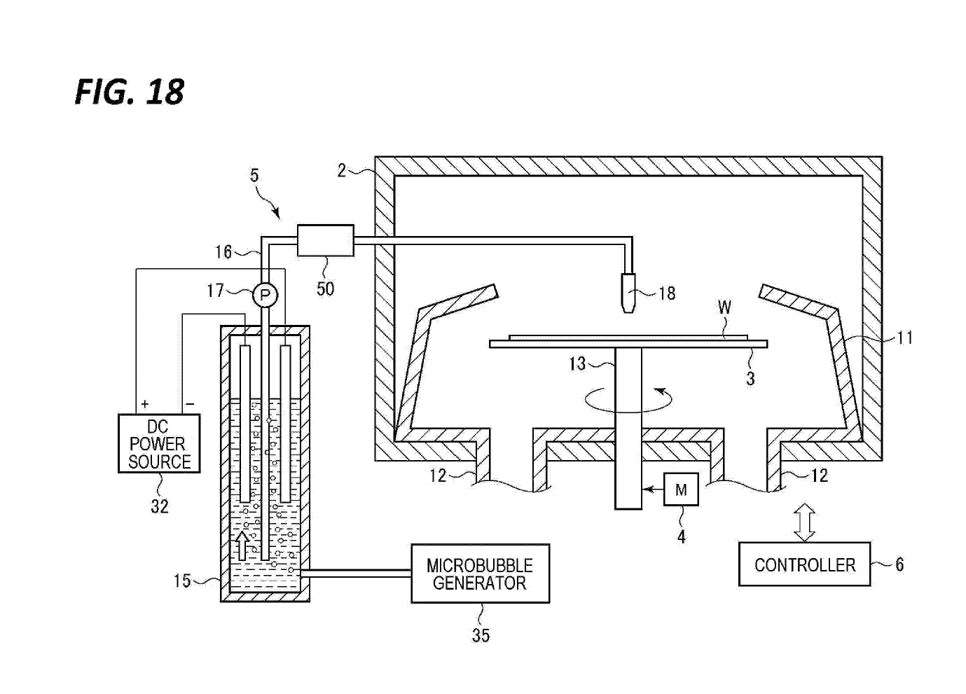

FIG. 18 illustrates an example in which the ion removal filter 50 of FIG. 11 is added to the liquid processing apparatus of FIG. 9.

### Third Exemplary Embodiment

Next, a third exemplary embodiment will be described.

In the third exemplary embodiment, charged minute metal-containing impurities in the liquid are removed from a supply system of the liquid used in the liquid processing, and charging of a wafer as a workpiece is controlled, so that the metal-containing impurities remaining in the liquid are suppressed from being attached to a wafer, which is a workpiece, by an electrostatic force. That is, the third exemplary embodiment is a combination of the first exemplary embodiment and the second exemplary embodiment. Similarly to the first exemplary embodiment and the second exemplary embodiment, the minute metal-containing impurities typically have a particle-like shape and a size of 10 nm or less, but not limited thereto. The charged metal-containing impurities include an ionic form, but not limited to the ionic form.

The combination is arbitrary. The first example, the second example, or the third example of the first exemplary embodiment may be used in combination with one of the first example, the second example, the third example, the fourth example, the fifth example, or the sixth example of the second exemplary embodiment. Alternatively, the first example, the second example, or the third example of the first exemplary embodiment may be used in combination with any appropriate combination of the first to sixth examples of the second exemplary embodiment. For example, the first example, the second example, or the third example of the first exemplary embodiment may be used in combination with a combination of the first example or the second example with the third example or/and the fourth example of the second exemplary embodiment.

As described above, when the removal of the metal-containing impurities in the liquid and the charging control of the wafer serving as a workpiece are used in combination, the amount of the metal-containing impurities in the liquid is reduced, and the metal-containing impurities are suppressed from being attached to the wafer by the electrostatic force. Therefore, the metal contamination of the wafer may be considerably effectively suppressed.

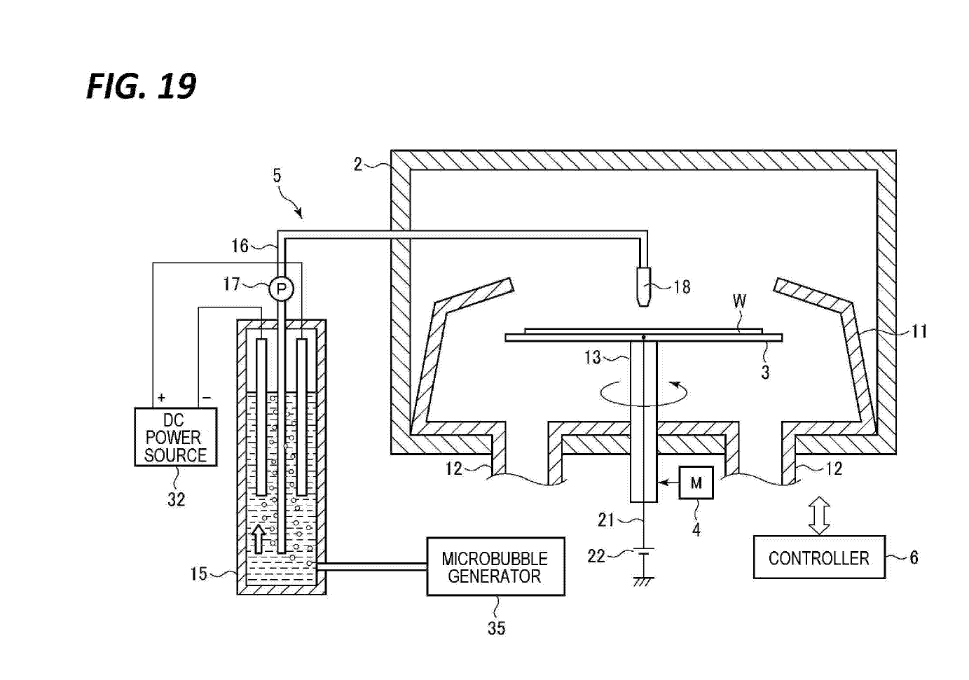

Among those, the combination of the first example or the second example of the first exemplary embodiment with the first example or the second example of the second exemplary embodiment is particularly effective as a simple configuration using static electricity. FIG. 19 illustrates a combination of the second example of the first exemplary embodiment with the second example of the second exemplary embodiment. Of course, the ion removal filter or the distillative purification unit, or both may be further provided in the apparatus of FIG. 19. Alternatively, the fifth example or the sixth example of the second exemplary embodiment may be combined therewith.

### Effect by Exemplary Embodiments

As described above, in the present exemplary embodiments, it is newly found that the liquid (e.g., IPA) used in the liquid processing contains charged minute metal-containing impurities typically having a particle-like shape and a size of 10 nm or less, which have conventionally not been recognized as being contained therein. Based on this, the metal-containing impurities are suppressed from being attached to the wafer by controlling charging of the wafer, or removing the metal-containing impurities from the liquid, or performing both. Accordingly, since the metal contamination of the wafer is effectively suppressed, it is possible to cope with miniaturization of semiconductor devices.

<Other Applications>

Further, the present disclosure is not limited to the above-described exemplary embodiment, and various modifications may be made thereto. For example, in the above exemplary embodiments, descriptions were made on a case where a wafer serving as a workpiece is held on a spin chuck and rotated, and a liquid is supplied to the wafer, so that the liquid is dispersed to the entire surface of the wafer, thereby performing a liquid processing. However, the configuration is not limited as long as the processing is performed by supplying a liquid to a workpiece.

In addition, in the above exemplary embodiments, the method of controlling the charging of the wafer serving as a workpiece and the method of removing the metal-containing impurities from the liquid are merely illustrative, and it is a matter of course that other methods may be used.

Further, in the above exemplary embodiments, a semiconductor wafer was used as a workpiece, but not limited thereto. As long as it is a workpiece to which charged minute metal-containing impurities may be attached, the present disclosure is applied thereto.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A method of performing a liquid processing on a workpiece by a liquid containing charged minute metal-containing impurities, using a liquid processing apparatus including: a holding unit configured to hold the workpiece; and a liquid supplying mechanism configured to supply a liquid to the workpiece held by the holding unit, the method comprising:
controlling charging of the workpiece held by the holding unit to suppress the metal-containing impurities from being attached to the workpiece by an electrostatic force.

2. A method of performing a liquid processing on a workpiece by a liquid containing charged minute metal-containing impurities, using a liquid processing apparatus including: a holding unit configured to hold the workpiece; and a liquid supplying mechanism configured to supply a liquid to the workpiece held by the holding unit, the method comprising:
removing the metal-containing impurities contained in the liquid while supplying the liquid to the workpiece held by the holding unit.

3. A method of performing a liquid processing on a workpiece by a liquid containing charged minute metal-containing impurities, using a liquid processing apparatus including: a holding unit configured to hold the workpiece; and a liquid supplying mechanism configured to supply a liquid to the workpiece held by the holding unit, the method comprising:
removing the metal-containing impurities contained in the liquid while supplying the liquid to the workpiece held by the holding unit; and
controlling charging of the workpiece held by the holding unit to suppress the metal-containing impurities remaining in the liquid from being attached to the workpiece by an electrostatic force.

4. The method of claim 1, wherein the charging of the workpiece is controlled by grounding the holding unit.

5. The method of claim 1, wherein the charging of the workpiece is controlled by applying a DC voltage to the holding unit.

6. The method of claim 1, wherein the charging of a front surface of the workpiece is controlled by supplying pure water to a rear surface of the workpiece held by the holding unit.

7. The method of claim 2, wherein the metal-containing impurities contained in the liquid are removed by storing the liquid in a storage unit, immersing a pair of electrodes in the liquid in the storage unit, and applying a voltage between the electrodes to form an electric field, thereby trapping the metal-containing impurities contained in the liquid to the electrodes by an electrostatic force.

8. The method of claim 7, wherein the trapping of the metal-containing impurities to the electrodes is facilitated by supplying microbubbles into the liquid stored in the storage unit from a lower side of the electrodes, and adsorbing the metal-containing impurities into the microbubbles while the microbubbles float in the liquid.

9. The method of claim 2, wherein the metal-containing impurities are removed by providing a filter capable of removing charged metal-containing impurities, in a liquid supply pipe configured to supply the liquid to the workpiece held by the holding unit.

10. The method of claim 9, wherein the filter includes a cation removal filter and an anion removal filter.

11. The method of claim 2, wherein the metal-containing impurities are removed from the liquid by distillatively purifying the liquid.

12. The method of claim 2, wherein a material having a high adsorptivity with respect to the metal-containing impurities in the liquid is used in at least a part of a liquid supply path configured to supply the liquid to the workpiece.

13. The method of claim 2, wherein a metal-containing impurity removing unit including an adsorption member made of a material having a high adsorptivity with respect to the metal-containing impurities in the liquid is provided in a liquid supply path configured to supply the liquid to the workpiece.

14. The method of claim 13, wherein the metal-containing impurities are removed from the adsorption member after the metal-containing impurities are adsorbed to the adsorption member.

15. The method of claim 12, wherein the material having a high adsorptivity with respect to the metal-containing impurities has a surface potential in the liquid having a sign opposite to a charge or a surface potential of the metal-containing impurities in the liquid.

16. The method of claim 15, wherein an index of the surface potential is an isoelectric point obtained from a zeta potential or a zeta potential measurement of particles constituting the material having a high adsorptivity with respect to the metal-containing impurities.

17. The method of claim 15, wherein an index of the surface potential is a dipole moment of composition of a compound constituting the material having a high adsorptivity with respect to the metal-containing impurities.

18. The method of claim 12, wherein the material having a high adsorptivity with respect to the metal-containing impurities in the liquid is charged.

19. The method of claim 1, wherein the metal-containing impurities are 10 nm or less in size.

20. An apparatus for performing a liquid processing on a workpiece by a liquid containing charged minute metal-containing impurities, the apparatus comprising:
a holding unit configured to hold the workpiece; and
a liquid supplying mechanism configured to supply a liquid to the workpiece held by the holding unit,
wherein the apparatus further comprises a charging controlling unit configured to control charging of the workpiece held by the holding unit, and
the metal-containing impurities are suppressed from being attached to the workpiece by an electrostatic force, by the charging controlling unit.

21. An apparatus for performing a liquid processing on a workpiece by a liquid containing charged minute metal-containing impurities, the apparatus comprising:
a holding unit configured to hold the workpiece; and
a liquid supplying mechanism configured to supply a liquid to the workpiece held by the holding unit,
wherein the apparatus further comprises a metal-containing impurity removing unit configured to remove the metal-containing impurities contained in the liquid while supplying the liquid to the workpiece held by the holding unit from the liquid supplying mechanism.

22. An apparatus for performing a liquid processing on a workpiece by a liquid containing charged minute metal-containing impurities, the apparatus comprising:
a holding unit configured to hold the workpiece; and
a liquid supplying mechanism configured to supply a liquid to the workpiece held by the holding unit,
wherein the apparatus further comprises:
a metal-containing impurity removing unit configured to remove the metal-containing impurities contained in the liquid while supplying the liquid to the workpiece held by the holding unit from the liquid supplying mechanism; and
a charging controlling unit configured to control charging of the workpiece held by the holding unit,
the metal-containing impurities in the liquid are removed by the metal-containing impurity removing unit, and
the metal-containing impurities remaining in the liquid are suppressed from being attached to the workpiece by an electrostatic force, by the charging controlling unit.

23. The apparatus of claim 20, wherein the charging controlling unit controls the charging of the workpiece by grounding the holding unit.

24. The apparatus of claim 20, wherein the charging controlling unit includes a DC power source configured to apply a DC voltage to the holding unit, and
the charging of the workpiece is controlled by applying the DC voltage from the DC power source to the holding unit.

25. The apparatus of claim 20, wherein the charging controlling unit includes a pure water supplying unit configured to supply pure water to a rear surface of the workpiece held by the holding unit, and
the charging of a front surface of the workpiece is controlled by supplying the pure water from the pure water supplying unit to the rear surface of the workpiece.

26. The apparatus of claim 21, further comprising:
a storage unit configured to store the liquid;
a pair of electrodes immersed in the liquid in the storage unit; and
a DC power source configured to apply a DC voltage between the pair of electrodes to form an electric field,
wherein, when the electric field is formed, the metal-containing impurities contained in the liquid are trapped to the electrodes by an electrostatic force, and the metal-containing impurities contained in the liquid are removed.

27. The apparatus of claim 26, further comprising:
a microbubble generator configured to supply microbubbles into the liquid stored in the storage unit from a lower side of the electrodes,
wherein the trapping of the metal-containing impurities to the electrodes is facilitated by adsorbing the metal-containing impurities into the microbubbles while the microbubbles float in the liquid.

28. The apparatus of claim 21, wherein the liquid supplying mechanism includes a liquid supply pipe configured to supply the liquid to the workpiece held by the holding unit,
the apparatus further comprises a filter provided in the pipe and configured to remove charged metal-containing impurities, and
the metal-containing impurities are removed by the filter.

29. The apparatus of claim 28, wherein the filter includes a cation removal filter and an anion removal filter.

30. The apparatus of claim 21, further comprising:
a distillative purification unit configured to distillatively purify the liquid,
wherein the metal-containing impurities are removed from the liquid by distillatively purifying the liquid by the distillative purification unit.

31. The apparatus of claim 21, wherein a material having a high adsorptivity with respect to the metal-containing impurities in the liquid is used in at least a part of a liquid supply path configured to supply the liquid to the workpiece.

32. The apparatus of claim 21, wherein a metal-containing impurity removing unit including an adsorption member made of a material having a high adsorptivity with respect to the metal-containing impurities in the liquid is provided in a liquid supply path configured to supply the liquid to the workpiece.

33. The apparatus of claim 32, further comprising:
a regeneration liquid supply line configured to supply a liquid that removes the metal-containing impurities from the adsorption member after the metal-containing impurities are adsorbed to the adsorption member.

34. The apparatus of claim 31, wherein the material having a high adsorptivity with respect to the metal-containing impurities has a surface potential in the liquid having a sign opposite to a charge or a surface potential of the metal-containing impurities in the liquid.

35. The apparatus of claim 34, wherein an index of the surface potential is an isoelectric point obtained from a zeta potential or a zeta potential measurement of particles constituting the material having a high adsorptivity with respect to the metal-containing impurities.

36. The apparatus of claim 34, wherein an index of the surface potential is a dipole moment of composition of a compound constituting the material having a high adsorptivity with respect to the metal-containing impurities.

37. The apparatus of claim 31, further comprising:
a unit configured to charge the material having a high adsorptivity with respect to the metal-containing impurities in the liquid.

38. The apparatus of claim 20, wherein the metal-containing impurities are 10 nm or less in size.
